(19) United States
(12) Patent Application Publication
(10) Pub. No.: US 2014/0173381 A1
(43) Pub. Date: Jun. 19, 2014

(54) BIT ERROR DETECTION AND CORRECTION WITH ERROR DETECTION CODE AND LIST-NPMLD

(71) Applicant: QUANTUM, INC., San Jose, CA (US)

(72) Inventors: Jaewook Lee, Irvine, CA (US); Suayb S. Arslan, Irvine, CA (US); Turguy Goker, Solana Beach, CA (US)

(73) Assignee: QUANTUM, INC., San Jose, CA (US)

(21) Appl. No.: 13/719,777

(22) Filed: Dec. 19, 2012

(51) Int. Cl. H03M 13/05

(52) U.S. Cl. CPC H03M 13/05
USPC 714/769

(57) ABSTRACT

A method for reducing the number of error events in a transmitted data stream (34) comprises the steps of (i) generating at least a first most probable sequence (16(1)) and a second most probable sequence (16(2)) with a detection algorithm (12); (ii) determining if a first correctable error occurred in the first most probable sequence (16(1)) with an EDC decoder (14); and (iii) determining if a second correctable error occurred in the second most probable sequence (16(2)) with the EDC decoder (14). Additionally, the steps of determining if a first correctable error occurred and determining if a second correctable error occurred can be performed substantially simultaneously. The method can further comprise computing a plurality of path metrics (42) for the transmitted data stream (34); and selecting a first q smallest path metrics out of the first and second most probable sequences (16(1)), (16(2)) with a Q value selector (44).

### BACKGROUND

Noise-Predictive Maximum Likelihood Detection (“NPMLD”) is an advanced digital signal-processing method that can be used with magnetic data storage systems, such as tape drives, hard disk drives, etc., that operate at high linear recording densities. Additionally, NPMLD can refer to a family of sequence-estimation data detectors, which arise by embedding a noise prediction/whitening process into the branch metric computation of a Viterbi algorithm. Relatively reliable operation of the prediction/whitening process can be achieved by using hypothesized decisions associated with the branches of a trellis on which the Viterbi algorithm operates, as well as tentative decisions corresponding to a path memory associated with each trellis state. The NPMLD detectors can thus be viewed as a family of reduced-state sequence-estimation detectors offering a range of implementation complexities, where complexity is essentially governed by the number of detector states. As such, NPMLD can be used for retrieving data recorded on the magnetic medium since the data may be read back as a weak and noisy analog signal by the read head. Because the goal of NPMLD is to minimize the influence of noise in the detection process, it allows recording at higher areal densities than other detection schemes.

Bit errors coming out of a data detector (e.g., an NPMLD detector) can be corrected by using an Error Correction Code (ECC) like a Reed-Solomon code, for example. However, the ECC cannot correct bit errors if the number of bit errors is larger than a certain threshold (i.e. if the number of bit errors is larger than an error correction capability). Therefore, an efficient bit error reduction scheme is required after the data detector and before the ECC.

In a traditional method, a post-Viterbi processing is applied at the output of the NPMLD to correct some of the dominant error events. Post processing is a low-complexity operation, usually employed after data detection algorithms to improve Bit Error Rate (BER) performance of magnetic recording systems. Post processing has been shown to be helpful when the distributions of error events at the output of the NPMLD are not even and the distributions are used at the post processor. In other words, some dominant error events are identified first, and then the entire post processor is designed to detect and correct those dominant error events. One of the advantages of post processing is its low complexity. In particular, it has been found that the use of such an approach usually leads to only a moderate increase in implementation complexity. However, post processors are often sub-optimal solutions and are usually not robust, i.e. the post processors attempt to correct dominant error events, but at the expense of leading to other unwanted error events that are not originally part of the NPMLD output. Although some threshold-based post processors have been introduced without using any extra redundancy, they are not practical. Additionally, such threshold-based post processors have also been found to be unreliable and often they have not lead to improved performance. Thus, post processing schemes based on Error Detection Codes (sometimes referred to herein as “EDC” or “EDCs”) became more popular and were used in various ways at the expense of a slight penalty at code rate.

### SUMMARY

The present invention is directed to a method for reducing the number of error events in a transmitted data stream. In certain embodiments, the method comprises the steps of (i) generating at least a first most probable sequence and a second most probable sequence with a detection algorithm; (ii) determining if a first correctable error occurred in the first most probable sequence with an EDC decoder; and (iii) determining if a second correctable error occurred in the second most probable sequence with the EDC decoder.

It should be noted that although such embodiments of the method disclosed with regard to the present invention are described as merely including the step of generating at least a first most probable sequence and a second most probable sequence with a detection algorithm, the method can be designed to generate greater than two most probable sequences with the detection algorithm. More particularly, the proposed method and detection algorithm can maintain and/or generate a list of the N most probable sequences (per state of a trellis) based on the observation that most of the error events can be recovered by finding a set of most likely paths, including the maximum likelihood path. Additionally, as provided herein, a periodic decision-making process is employed for every period, i.e. for every P bits of data, based on error detection codes in order to detect and correct at least some of the error events.

In one embodiment, the steps of determining if a first correctable error occurred and determining if a second correctable error occurred are performed substantially simultaneously.

Additionally, in some embodiments, the step of determining if a first correctable error occurred includes the EDC decoder having a first parity check code that is used to evaluate the first most probable sequence. Further, in such embodiments, the step of determining if a second correctable error occurred can include the EDC decoder having a second parity check code that is used to evaluate the second most probable sequence. In one such embodiment, the step of determining if a first correctable error occurred further includes the first parity check code utilizing three parity bits that are added to a first portion of the transmitted data stream to evaluate the first most probable sequence. Moreover, in such embodiment, the step of determining if a second correctable error occurred can further include the second parity check code utilizing three parity bits that are added to a second portion of the transmitted data stream to evaluate the second most probable sequence.

In another embodiment, the step of determining if a first correctable error occurred includes the EDC decoder having a first cyclic redundancy check code that is used to evaluate the first most probable sequence. In such embodiment, the step of determining if a second correctable error occurred can also include the EDC decoder having a second cyclic redundancy check code that is used to evaluate the second most probable sequence.

In one embodiment, the method as described herein above can further comprise the step of separating the transmitted data stream into a plurality of data chunks, with each data chunk including a specified number of bits. In such embodiment, the step of generating includes the detection algorithm generating at least a first most probable sequence and a second most probable sequence for each data chunk.

Additionally, in certain embodiments, the method as described herein above further comprises the steps of computing a plurality of path metrics for the transmitted data stream, and selecting a first q smallest path metrics out of the first most probable sequence and the second most probable sequence with a Q value selector. In one such embodiment, the step of determining if a first correctable error occurred includes evaluating the first q smallest path metrics with the EDC decoder to determine if a first correctable error occurred in the first most probable sequence. Additionally, in such embodiment, the step of determining if a second correctable error occurred can further include evaluating the first q smallest path metrics with the EDC decoder to determine if a second correctable error occurred in the second most probable sequence. Moreover, in one embodiment, the method can further comprise the step of updating the plurality of path metrics based on the evaluation of the first q smallest path metrics by the EDC decoder.

Additionally, the present invention is further directed to a method for detecting bit errors in a transmitted data stream, the method comprising the steps of (i) generating at least a first most probable sequence and a second most probable sequence with a detection algorithm; (ii) computing a plurality of path metrics for the transmitted data stream; and (iii) selecting a first q smallest path metrics out of the first most probable sequence and the second most probable sequence with a Q value selector.

Further, in another embodiment, the present invention is also directed to an error correction system for reducing the number of error events in a transmitted data stream, the error correction system comprising a detection algorithm that generates at least a first most probable sequence and, a second most probable sequence; and an EDC decoder that determines (i) if a first correctable error occurred in the first most probable sequence, and (ii) if a second correctable error occurred in the second most probable sequence.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a schematic illustration of an embodiment of a bit error detection and correction system having features of the present invention, the bit error detection and correction system including a detection algorithm;

FIG. 2 is a schematic illustration demonstrating a computation of three parity bits for dominant error event detection that can be utilized within the bit error detection and correction system of FIG. 1;

FIG. 3 is a statistical representation of dominant error events detectable from a Linear Tape Open (LTO) system;

FIG. 4 is a schematic illustration of an embodiment of an update stage usable as part of the detection algorithm of FIG. 1;

FIG. 5 is a graphical representation of simulation results using a Lorentzian channel model using fixed D_{c} and β, with perfect error detection;

FIG. 6 is a graphical representation of simulation results using a Lorentzian channel model using fixed β, with various D_{c} values;

FIG. 7 is a graphical representation of simulation results using a Lorentzian channel model using fixed D_{c}, with various β values (also set are N=3 and P=198 bits); and

FIG. 8 is a graphical representation of simulation results illustrating BER performances for fixed SNR with varying P.

### DESCRIPTION

As provided in detail herein, a List-Noise Predictive Maximum Likelihood Detection (List-NPMLD) algorithm (also referred to herein as a “detection algorithm”) based on periodic insertions of parity check codes and cyclic redundancy check (CRC) codes is introduced for magnetic recording channels in a bit error detection and correction system (also sometimes referred to herein as an “error correction system”). The detection algorithm is an increased performance sequence estimation algorithm which preserves one or more of the desirable properties of a conventional NPMLD, such as embedded noise prediction.

In particular, the proposed detection algorithm keeps a list of candidate paths (N most probable sequences (or candidates) per state of a trellis) based on the observation that most of the error events can be recovered by finding a set of most likely paths, including the maximum likelihood path. As provided in detail herein, a periodic decision-making process is employed for every period (i.e. for every P bits of data) based on error detection codes in order to detect and correct at least some of the error events.

For example, for representative recording channel and signal-to-noise ratio (SNR) conditions, when using N=3 (i.e. three most probable sequences) and P=200 (i.e. periods that include two hundred bits of data), the List-NPMLD algorithm provided herein can correct approximately 92% of the error events at the output of a conventional NPMLD algorithm. Additionally, the List-NPMLD algorithm embodiments described herein do not change the distributions of error events and hence can easily be combined with a traditional post processing method that targets a specific set of dominant error events. Therefore, as described herein, the List-NPMLD algorithm can either be considered as an alternative to traditional post processing methods, or as a complementary method that can be combined with other post processing methodologies. Unlike traditional post processing methodologies, the detection algorithm of the present invention utilized with the error correction system does not need to know the error event distribution. Moreover, if the EDC works perfectly, it does not add any new error events caused by false corrections. Additionally, as discussed herein, simulation results show that the proposed List-NPMLD algorithm combined with an EDC can improve BER performance at magnetic recording channels.

It should be noted that the present detection algorithm is useful with various high density data recording channels, such as a tape drive system, e.g., an LTO Gen7 tape drive, a hard disk drive system, or other suitable high density data recording channels. Additionally, the proposed detection algorithm can also be used in other suitable applications.

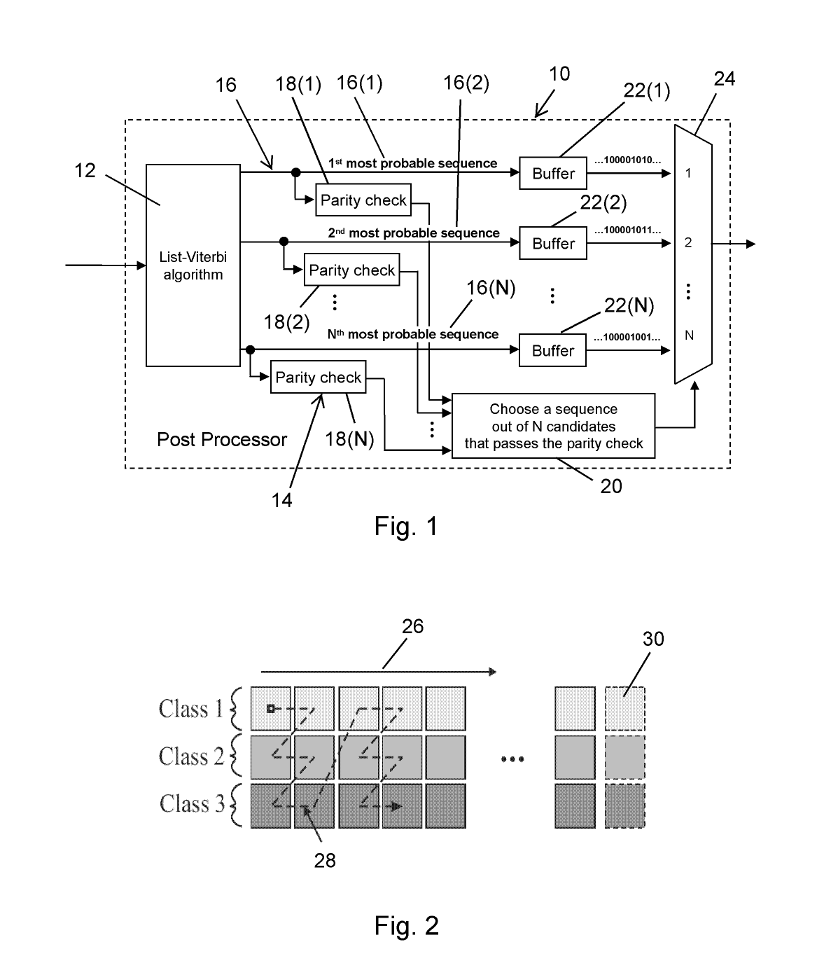

FIG. 1 is a schematic illustration of an embodiment of a bit error detection and correction system 10 having features of the present invention. In particular, as illustrated, the error correction system 10 utilizes a combination of a List-Viterbi (used interchangeably herein with “List-NPMLD”) detection algorithm 12 (“detection algorithm”), and error detection code (also sometimes referred to herein as “EDC codes”, “parity check codes” or “CRC codes”) decoders 14 for reducing the number of error events at the output of the Viterbi (used interchangeably herein with “NPMLD”).

As used herein, a Viterbi algorithm is a dynamic programming algorithm for finding the most likely sequence of hidden states—called the Viterbi path—that results in a sequence of observed events. Additionally, an EDC is a set of suitable functions that add fixed-length redundancies (tags) to a message far error detection. Since the receiver knows the functional operation of the EDC, the tags can be recomputed at the receiver. Then the tags are compared with the original tags to decide whether there has been any change in the original message (i.e. bit errors) during transmission. If the comparison indicates a success (i.e. no bit errors), the EDC decoder 14 flags ‘pass’; otherwise, the EDC decoder 14 flags ‘failure’.

Upon detection of an error during any given data transmission operation (a “data error”), the detection algorithm 12 determines the most probable paths or most probable sequences 16 in which a correctable error may have occurred. In the embodiment shown in FIG. 1, the List-Viterbi detection algorithm 12 generates N most probable sequence candidates, as opposed to a Viterbi algorithm, which generates only one maximum likelihood candidate. More particularly, as shown in FIG. 1, the detection algorithm 12 generates a first most probable sequence 16(1), a second most probable sequence 16(2), and so on, up to and including an N^{th} most probable sequence 16(N).

At the output of the List-Viterbi detection algorithm 12, the EDC (i.e. parity check code, CRC code) decoders 14 decide which sequence is valid (e.g., passing parity check or CRC) because an error-free sequence will pass the parity check. Stated in another fashion, at the output of the detection algorithm 12, each most probable sequence 16 is evaluated via a parity check, i.e. the first most probable sequence 16(1) is evaluated via a first parity check 18(1), the second most probable sequence 16(2) is evaluated via a second parity check 18(2), and so on, up to and including the N^{th} most probable sequence 16(N) being evaluated via an N^{th} parity check 18(N). Additionally, in one embodiment, each of the parity checks 18(1)-18(N) for each of the most probable sequences 16(1)-16(N), respectively, are performed substantially simultaneously. As utilized herein, parity checking refers to the use of parity bits, which are added to many or all data units that are transmitted, to check that the data has been transmitted accurately. The parity bits are bits that are added to increase the likelihood or ensure that the number of bits with the value of one in any given set of bits is either even (“even parity”) or odd (“odd parity”). Further, a selector 20 of the error correction system 10 sends out one sequence that passes the corresponding parity check as a final decision. With this design, the final decisions are already verified to be substantially or completely error-free as long as the EDC decoding was successful.

It is recognized that although the EDC decoders 14 are described in detail herein with the use of parity check codes, the EDC decoders 14 can also be used effectively utilizing CRC codes, and there is no intent to limit the scope and breadth of the present invention due to the more detailed description in relation to the parity check codes.

Additionally, it should be noted that, as shown in FIG. 1, during the EDC 14 process, each of the most probable sequences 16 can be temporarily held in a corresponding buffer. For example, while the parity checks of the EDC 14 are being performed, the first most probable sequence 16(1) is temporarily held in a first buffer 22(1), the second most probable sequence 16(2) is temporarily held in a second buffer 22(2), and so on, with the N^{th} most probable sequence 16(N) being held in an N^{th} buffer 22(N). The most probable sequences 16(1)-16(N) are temporarily held in the buffers 22(1)-22(N), respectively, until a final decision, is made of the sequence that passes the corresponding parity check. At that point, the most probable sequences 16(1)-16(N) are then passed on to an outputter 24 from which the final decision is passed based on the outcome of the various parity checks 18(1)-18(N).

In one embodiment, three parity bits (i.e. three-bit tags) are added to the input data for dominant error event detection. In this embodiment, the parity bit is a bit that is added to increase the likelihood or ensure that the number of bits with the value of one in any given set of bits is either even or odd, depending on the type of parity chosen. For example, for even parity, if a given set of data bits (i.e. a given set of 0's and 1's) includes an odd number of 1's, then the parity bit chosen will be a 1, so that the total number of 1's is even. Additionally, for even parity, if a given set of data bits includes an even number of 1's, then the parity bit chosen will be a 0, so that the total number of 1's remains even. Conversely, for odd parity, if a given set of data bits includes an odd number of 1's, then the parity bit chosen will be a 0, so that the total number of 1s remains odd. Further, for odd parity, if a given set of data bits includes an even number of 1's, then the parity bit chosen will be a 1, so that the total number of 1's is odd. Thus, for performing a parity check utilizing even parity, (i) if the total number of 1's in a given set of data bits (including the parity bit) is even, then no parity error has occurred during transmission of the data; and (ii) if the total number of 1's in a given set of data bits (including the parity bit) is odd, then that is evidence that a parity error occurred during transmission. Conversely, for performing a parity check utilizing odd parity, (i) if the total number of 1's in a given set of data bits (including the parity bit) is odd then no parity error has occurred during transmission of the data; and (ii) if the total number of 1's in a given set of data bits (including the parity bit) is even, then that is evidence that a parity error occurred during transmission.

FIG. 2 is a schematic illustration demonstrating a computation of three parity bits for dominant error event detection that can be utilized within the bit error detection and correction system 10 of FIG. 1. Stated another way, FIG. 2 illustrates an embodiment of a suitable design for the parity check process, i.e. how data bits of each chunk of data are written as a means to compute parities, that is usable as part of the present invention.

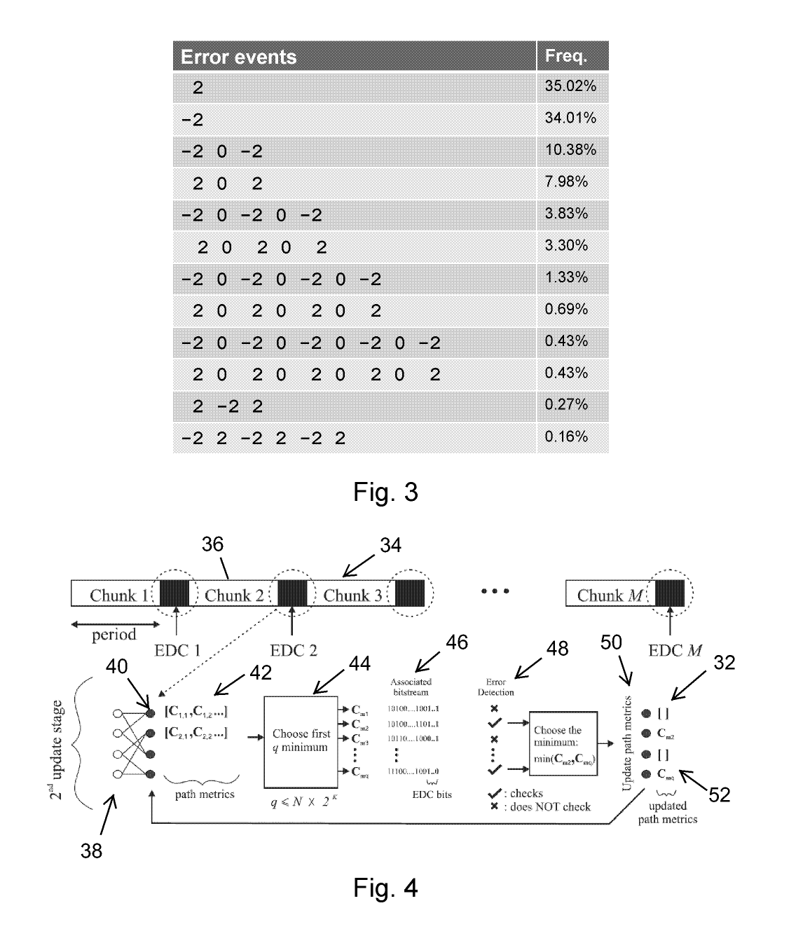

FIG. 3 is a statistical representation of dominant error events detectable from a particular system, i.e. an LTO system. In particular, FIG. 3 illustrates the twelve most common dominant error events, which encompass approximately 98% of the dominant error events from an LTO system.

Referring back to FIG. 2, in one non-exclusive application, Even parity can be assumed for convenience in the ordered data bits as shown in FIG. 2 to detect dominant error events in an LTO system efficiently (see FIG. 3). In this application, the ordered data bits are arranged into three rows of data (i.e. Class 1, Class 2 and Class 3, as shown in FIG. 2), with the parities for the three rows of data being computed from left to right, as indicated by arrow 26. Additionally, arrow 28 indicates the direction that the data bits of each chunk are written into the boxes. For example, as shown in FIG. 2, to detect the dominant error events (e.g., for an LTO system, as illustrated in FIG. 3), the data bits can be written in order such that as bit 0 is from Class 1, bit 1 is from Class 1, bit 2 is from Class 2, bit 3 is from Class 2, bit 4 is from Class 3, and bit 5 is from Class 3, with the bits then returning to Class 1 (for two more bits), Class 2 (for two more bits) and Class 3 (for two more bits), and so on as necessary.

Further, as shown, a parity bit 30 value is computed for each row, and therefore three parity bits 30 are appended at the end of each set of data bits. Note that a single parity bit 30 is in fact a 1-bit CRC code with the generator polynomial X+1. In other words, three CRC bits can be used for different equal-size classes (Class 1, Class 2 and Class 3 in FIG. 2) of data bits. Assuming that only a single error event happens within a code word, this 3-bit parity code can detect the error events of the form (in NRZ format): {±2}, {±2 0±2}, {±2±2±2}, {±2 0±2 0±2}, {±2 0±2 0±2 0±2} and {±2 0±2 0±2 0±2 0±2}, as shown in FIG. 3. More particularly, in FIG. 3, {±2} are indicative of a one bit error, {±2 0±2} are indicative of a two bit error in a three bit length, {±2 0±2 0±2} are indicative of a three bit error in a five bit length, (±2 0±2 0±2 0±2) are indicative of a four bit error in a seven bit length, and (±2 0±2 0±2 0±2 0±2) are indicative of a five bit error in a nine bit length. Additionally, in FIG. 3, it should be noted that the first eleven types of dominant error events (of the twelve) listed are detectable with the arrangement described herein because at least one Class has only a single error (indicated by a±2), whereas the last type of dominant error event listed is not detectable as each of the Classes has an even number of errors. Thus, in this embodiment, these detectable error events cover nearly 98% of the total error events at the output of a data detector in an LTO system. Note that if at least one of the classes of bits has an odd number of bit errors (i.e. parity failure), the designed parity code can detect error events successfully. Conversely, if the classes of bits have an even number of bit errors, the designed parity code is unable to detect error events successfully.

It should be noted that the present system as illustrated and described herein is not intended to identify and correct all bit errors, but rather to decrease the number of bit errors. Additionally, it should be noted that the specific percentages for the dominant error events as shown in FIG. 3 relate specifically to one particular LTO system, and the specific percentages for the dominant error events can vary depending on the type of recording medium and/or the recording densities.

Referring again to the embodiment illustrated in FIG. 1, it is understood that the proposed detection algorithm 12 (i.e. the List-NPMLD or List-Viterbi algorithm) is based on a periodic decision making process. Moreover, the proposed error correction system 10 demonstrates a method for incorporating detection codes within the List-Viterbi detection algorithm 12 to benefit from the detection of the errors that are decoded. In particular, the detection algorithm 12 is a combination of periodic updates and a parallel implementation of the detection algorithm 12 which simultaneously produces a rank ordered list of the N globally best (most probable) candidates 16 for each state in a periodic search of a trellis 38 (illustrated in FIG. 4). At the end of each period of bits, the detection algorithm 12 chooses one of 2^{K}N possible paths as the final decision of that update step. Here, the K is the order of the trellis 38 and the N is the number of candidates from the detection algorithm 12. This way, in an evolving trellis 38 tree, any bad candidates due to noise are removed from a given chunk-size (P bits, as used herein) trellis 38 section. By making an appropriate decision and corresponding updates, the number of error events are greatly reduced.

The detection algorithm 12 decodes the incoming signal waveform through continually computing the accumulated metrics and branch metrics at each time step. At the end of each period of decoded P bits, the accumulated metrics are updated if the error detection mechanism checks. In other words, the detection algorithm 12 makes a decision on previous bits (by choosing a path that passes the EDC decoding) and employs an update step before proceeding to the next decoding period of P bits. As the trellis 38 evolves in time, the detection algorithm 12 eliminates half of the possible paths, i.e. the false paths, in the trellis 38 at each time step. At the end of each P-bits period, a decision is made and an update step is executed on the accumulated metrics before proceeding to the decoding of the next chunk. The reason for such a periodic update is to increase the probability of correcting an error event (if there is any) before the trellis 38 evolves more and the detection algorithm 12 eliminates more false paths. This suggests that for a fixed N, if P is large, we expect less error corrections. On the contrary, one can choose P small to increase the probability of correcting a majority of the error events at the output of the NPMLD. However, having smaller P implies more frequent periodic updates meaning that more redundant bits are used for error detection. Thus, the proposed detection algorithm 12 offers a tradeoff, i.e., an improved performance is possible at the expense of a decreased user density.

FIG. 4 is a schematic illustration of an embodiment of an update stage 32 usable as part of the detection algorithm 12 of FIG. 1. More particularly, one example of the update and decision making process (here using N=2 and K=2) is shown in FIG. 4 that encompasses the modified List-Viterbi detection algorithm 12 usable as part of the error correction system 10.

Additionally, illustrated at the top of FIG. 4 is a data stream 34 that has been separated into a plurality of data chunks 36, with each data chunk 36 including a certain number of bits, i.e. each data chunk 36 has a certain period. As discussed herein, the size of the period (P) for each of the data chunks 36 can be varied. Generally speaking, the detection algorithm 12 is able to achieve a better performance with a shorter sequence (i.e. a shorter or smaller period, P, or a smaller number of bits in each data chunk 36), but there is a corresponding tradeoff related to an increase in complexity and redundancies that is necessary when utilizing smaller data chunks 36.

Further, as shown, each data chunk 36 is evaluated, with error events thus being detected, through the operation of a separate error detection code (EDC). Each EDC for each data chunk 36 can be equated with and/or represented by the update stage 32 illustrated in FIG. 4. In the embodiment shown in FIG. 4, the data stream 34 has been separated into M number of data chunks 36, which thus requires the use of M number of EDCs.

The detection algorithm 12 and/or the update stage 32 of the detection algorithm 12 is based on the trellis 38, with the trellis 38 encompassing a plurality of nodes 40. Additionally, as illustrated in FIG. 4, path metrics 42 are computed for each node 40 on the trellis 38. For example, path metrics [C_{1,1}, C_{1,2}, . . . ] are computed for the first node of the trellis 38, path metrics [C_{2,1}, C_{2,2}, . . . ] are computed for the second node of the trellis 38, and so on. The path metrics 42 correspond to the sequence candidates for each node 40 of the trellis 38. Stated another way, there is a bit sequence associated with each path metric 42. Further, the path metrics 42 are ordered in relation to each node 40 of the trellis 38 based on which sequence candidate is determined to be the most probable sequence, the second most probable sequence, the third most probable sequence, etc., up to the N^{th} most probable sequence. Thus, for example, for the first node, C_{1,1} is the most probable sequence, C_{1,2} is the second most probable sequence, etc. In establishing the order of the sequence candidates, the path metric 42 with the lowest number is determined to relate to (or otherwise identifies) the most probable sequence, the path metric 42 with the second lowest number is determined to relate to (or otherwise identifies) the second most probable sequence, and so on.

As described herein, the number of most probable sequences (N) identified can be varied. Generally speaking, the detection algorithm 12 is able to achieve a better performance with a larger number of most probable sequences (a larger N), but there is a corresponding tradeoff related to an increase in complexity and redundancies that is necessary when utilizing a greater number of most probable sequences.

Once the path metrics 42 have been computed for each node of the trellis 38, the update stage 32 next illustrates a C value selector 44 in which the first q smallest path metrics 42 are chosen out of all 2^{K}N possible paths from the List-Viterbi detection algorithm 12. The set of the first q smallest path metrics 42 as chosen via the operation of the Q value selector 44 is illustrated as C_{q}={Cₘ₁, Cₘ₂, . . . , C_{mq}}, with each chosen path metric 42 being associated with a corresponding associated bitstream 46. Additionally, as illustrated, each associated bitstream 46 includes EDC bits for purposes of decoding.

It should be noted that number of path metrics 42 chosen by the Q value selector 44 can be any number of candidates from all of the nodes 40 on the trellis 38, with a higher number generally leading to better performance, but also requiring greater complexity and redundancies for the detection algorithm 12 of the error correction system 10. For example, in different embodiments, the number of path metrics 42 chosen by the Q value selector 44 can be two, four, six, eight, ten, twelve, fourteen, or any other number.

The reason for utilizing the Q value selector 44 is to minimize false EDC checks caused by less probable sequence candidates (i.e. candidates with large accumulated metrics). Especially when P and N are large, the detection code is expected to see more false EDC checks. By choosing an appropriate q value with the Q value selector 44, the EDC is inhibited from checking false paths that potentially have more error events than the maximum likelihood path that fails the EDC decoding.

After selecting the smallest q accumulated path metrics 42 via operation of the value selector 44, based on the associated decoded bitstreams of q paths, an error detector 48 evaluates each associated bitstream 46 using EDC decoding. In FIG. 4, in the error detector 48, a check mark (“✓”) denotes that the corresponding EDC bits for each associated bitstream 46 do not detect any error and flags a 1, and an “x” denotes that the EDC bits detect bit errors and flags a 0. It should be noted that the operation of the error detector 48 usually only results in one check mark. However, in the example illustrated in FIG. 4, the second and q^{th} element of C_{q} have flagged 1's. Since EDC can only work up to a certain accuracy, it is possible that more than one path checks, as seen in this example. When more than one path checks (as in this example), the detection algorithm 12, i.e. the update stage 32, can choose the path with the smallest accumulated metric as the appropriate decision at this particular update step.

Finally, the accumulated path, metrics are updated with a metric updater 50 to provide updated path metrics 52. In this example, via the metric updater 50, the accumulated metrics of all the paths except the second and q^{th} paths, i.e. the paths that flagged 0s or “failed”, are discarded i.e., set to ∞ (or other typically large value). Additionally, the accumulated metrics that do not belong to C_{q} are also set to ∞. The updated path metrics 52 are then fed back into the update stage 32 as related to each node 40 on the trellis 38, and the process is repeated. Further, it should be noted that for those paths that failed, the next most probable sequence for that particular node 40 is chosen for the next pass through the update stage 32. For example, if the C_{1,1} path metric for the first node of the trellis 38 failed for the first pass through the update stage 32, on the next pass through the update stage 32, the C_{1,2} path metric for the first node of the trellis 38 would be utilized and/or evaluated.

In contrast to the passes through the update stage 32 that find one or more checks, as discussed above, it is possible that there is “no check” i.e., EDC indicates that none of the paths is correct. Since the detection algorithm 12 is expected to continue decoding, a decision should be made about which path is to be chosen. There are more than one type of decision as mentioned below. Additionally, the accumulated metrics are not updated if there is “no check”.

Type 1:

One of the simplest choices is to choose the path with a minimum accumulated metric. In other words, at each periodic update step, if the EDC indicates no path is reliable, the detection algorithm 12 decides that the correct path is the one with the smallest accumulated metric.

Type 2:

As previously noted, during application, the EDC flags either 0 or 1. Thus, if no path checks the EDC, every path flags a 0. However, the EDC might have the capability of flagging some number 0≦a≦1 based on the number of errors associated with the path (message) to which this EDC is appended. In other words, for example, low value of ‘a’ could mean more number of bit errors. In that case, if there is no path with a flag 1, the detection algorithm 12 might choose the path with the largest ‘a’.

It should be noted that the decision process is updated as each data chunk 6 is evaluated via the corresponding EDC, i.e. via the update stage 32. Accordingly, the results improve as they are updated by going through each of the data chunks 36, and by the time the M^{th} data chunk 36 is evaluated, the results should be relatively good or near perfect.

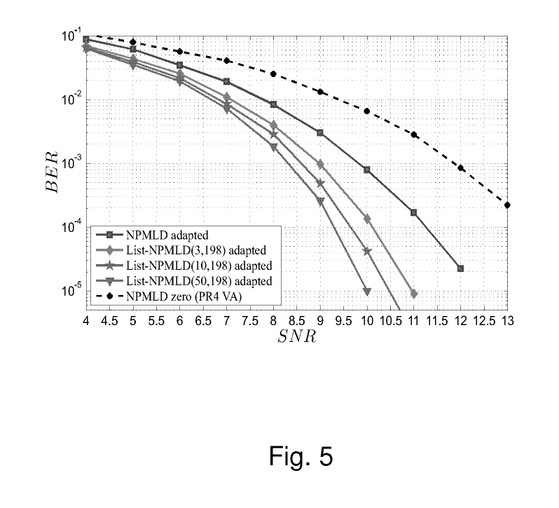

FIGS. 5-8 demonstrate certain simulation results that have been achieved during testing of the present invention. In all of the simulations reported herein, the order of the trellis, K, has been set to two (i.e. K=2), and the number of bits in the feedback loop, L, has been set to three (i.e. L=3). Thus, in such simulations, the trellis has four states and there are three bits in the feedback loop. Additionally, PR4 signaling is considered throughout the simulation testing.

Initially, FIG. 5 is a graphical representation of simulation results using a Lorentzian channel model using a linear recording density, D_{c} of 3.25 (i.e. D_{c}=3.25), a ratio of transition noise power to the total noise power, β, of 0.5 (i.e. β=0.5), and perfect error detection.

For a Lorentzian channel, the first order position jitter model is considered. Electronics and stationary transition noise samples are added to the signal waveform at the input of a low pass filter (LPF). Additionally, the signal-to-noise ratio (SNR) is computed at the input of the LPF and given by 2/(N₀+Nₘ) where N₀/2 and Nₘ/2 are the two sided spectral densities of two white Gaussian noise sources. Further, the ratio of the transition noise power to the total noise power is approximated by β=Nₘ/(N₀+Nₘ). Perfect timing recovery and a 5th Butterworth LPF with a 3-dB cut-off at the Nyquist frequency is also assumed. PR4 equalizer is based on the minimum mean square error criterion and length of the filter is as long as the channel impulse response. Whitening filter coefficients are selected using linear prediction in Least Mean Squares (LMS) sense based on the current noise samples wₙ.

As provided herein, FIG. 5 shows bit error rate (BER) performance results assuming perfect error detection (i.e. it was assumed that the detection code always finds the correct path if the correct path is within the group of N×2^{K} candidates; and q=N×2^{K} was set when assuming perfect error detection) for P=198 bits, D_{c}=3.25 and different N values as functions of SNR. Also included in FIG. 5 is the performance of the conventional NPMLD both for adapted whitener coefficients and zero coefficients. It should be noted that the remainder of the simulation results compare the performance with respect to NPMLD using adapted whitener coefficients. As can be observed at a BER of 1e⁻⁴, using N=50, a gain of almost 2 dB is possible over the conventional NPMLD. In a more practical scenario of N=3, more than 1 dB gain can be observed at the same operating BER. Those ideal error correction-based performance ryes may serve as benchmarks for the ultimate system performance.

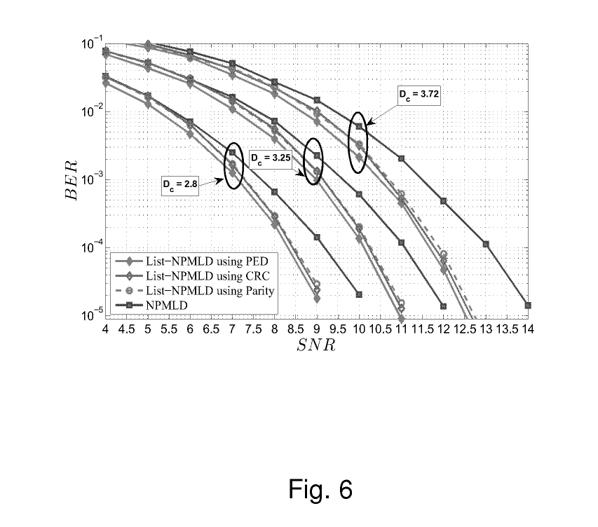

FIG. 6 is a graphical representation of simulation results using a Lorentzian channel model for various values of D_{c}, and with β set at 0.5. In these results, the performance of the proposed system is shown using a CRC code with a generator polynomial X⁴+1 and three parity bits. Additionally, the chunk size, P, is again set such that set P=198 bits, with β=0.5, and q=6 for N=3. It should be noted that with these parameter selections, one extra bit is used per 66-bit chunk (66B) for error detection. In order for a fair comparison, it is assumed that the channel bit duration T increases to TNPMLD=67×T/66 when simulating the NPMLD performance. As illustrated, linear density values Dc=2.8, 3.25 and 3.72 are assumed in FIG. 6 for the List-NPMLD system. This corresponds to simulating the NPMLD performance using PW50/T_{NPMLD}≈2.76, 3.2 and 3.66, respectively. The figure shows the performance of those detection codes with respect to the perfect error detection case. As illustrated in FIG. 6, the performance degradation due to using actual detection codes is minor and only noticeable at around 1e⁻² to 1e⁻³ BER range. It can also be observed that the gain increases slightly with growing Dc. This is usually because the proposed scheme treats the error events equally and shows increased performance at higher densities. Further, it can be noted that EDCs based on CRC and parity bits show similar results for the selected simulation parameters.

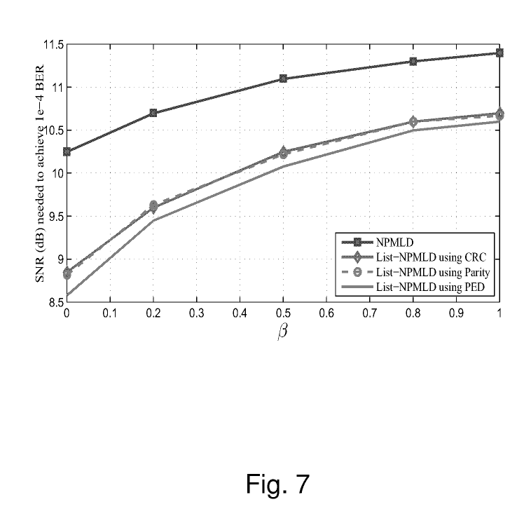

FIG. 7 is a graphical representation of simulation results using a Lorentzian channel model using fixed D_{c}, for various values of β, with other parameters set at N=3 and P=198 bits. More specifically, FIG. 7 illustrates the SNR needed to achieve a BER of 1e⁻⁴ using different β values (which was previously set to 0.5) at Dc=3.25. As expected, given a total noise power, increases in β result in increases in the transition noise with respect to white electronic noise. However, this does not mean that there will be a linear increase of correlated noise at the List-NPMLD input, because noise characteristics will change through the PR4 and whitener. As shown in FIG. 7, increases in β results in degraded performance of both the NPMLD and the List-NPMLD. It should be noted that the vertical distance of the performance curves shows the SNR gain that can be achieved. Additionally, it can be observed that around a 1 dB gain is possible for β≦0.5, and the performance slightly degrades for larger values of β.

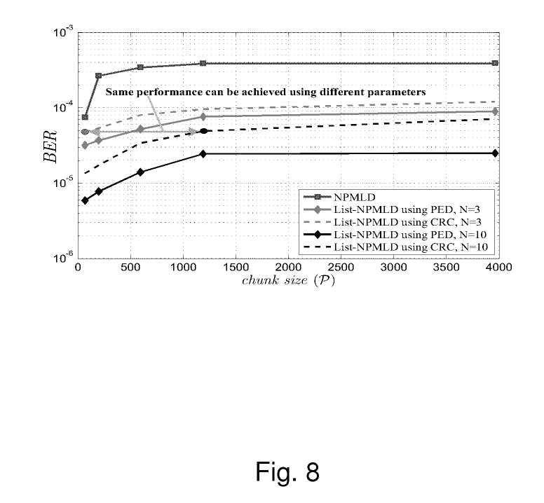

FIG. 8 is a graphical representation of simulation results illustrating BER performances for fixed SNR with varying P. In particular, FIG. 8 shows BER performances at SNR of 10.5 dB with varying P. In these simulations, the List-NPMLD system uses Dc=3.25 and the corresponding densities for an NPMLD system are≈3.11, 3.2, 3.23, 3.24, 3.25 for chunk sizes of 66, 198, 594, 1188 and 3960 bits, respectively. Initially, it may be observed that when N=10, the number of candidate paths are 80. Yet, the q value can be set such that q=12 to help the EDC to perform satisfactorily. As can be seen, the detection codes are highly challenged by the choice of q and the performance gap between the perfect error detection case and actual detection codes increases as the List-NPMLD uses larger N. As expected, increasing the chunk size decreases the gain and the number of redundancy bits per 66Bs. However, the performance degradation can be compensated for by using larger N. FIG. 8, for example, shows that using CRC bits, almost the same BER performance can be achieved with N=3 using P=66 bits (three bits per 66B) and N=10 using P=1188 bits (⅙ bit per 66B). This means that when employing fast list implementation algorithms, the complexity of which grows linearly with N, an almost 4 times increase in complexity leads to 18 times less redundancy use.

Finally, as provided herein, the following tables present the practical performance results of the application of the proposed detection algorithm 12 using LTO waveforms in Table I, Table II and Table ill for chunk sizes of P=200 bits, P=1,000 bits and P=2,000 bits, respectively. Initially, each table shows the number and types of error events (such as shown in FIG. 3) found when using a NPMLD (or Viterbi) detection algorithm (which equates to utilizing a value for N of one). Next, each table shows the number and types of error events found when using the List-NPMLD (or List-Viterbi) detection algorithm 12 (as modified based on the teachings provided herein) with different numbers for N (i.e. utilizing a different number of most probable sequences). More specifically, each table shows the number and types of error events when N is set at 2, 3, 5, 10 and 50.

As can be seen, the performance of the List-NPMLD detection algorithm utilizing any N is significantly better than the performance seen when simply utilizing the NPMLD detection algorithm. Moreover, as demonstrated in the tables, the performance of the List-NPMLD detection algorithm improves with increasing N, although such improvement is achieved at the expense of an increase in complexity and redundancies. For example, at P=200 bits, approximately 85% and 92% of the error events can be reduced using N=2 and N=3, respectively, as compared to the use of the NPMLD detection algorithm. Another way of looking at these results is to see the performance tradeoff between parameters N and P. For example, it can be observed that the proposed scheme with N=2 and P=200 bits gives almost the same performance compared to the system using N=5 and P=1,000 bits. However, the N=2 and P=200 setting requires almost 5 times the number of redundant bits for EDC, but only almost 40% circuit complexity as compared to those for the N=5 and P=1,000 setting.

TABLE I
Performance results with real LTO waveforms at P = 200

| Error Events in NRZ | NPMLD | | LNPMLD (2) | | LNPMLD (3) | | LNPMLD (5) | | LNPMLD (10) | | LNPMLD (50) | |
|---|---|---|---|---|---|---|---|---|---|---|---|---|
| {±2} | 1279 | (69.1%) | 174 | (61.4%) | 85 | (59.6%) | 53 | (62.3%) | 36 | (59.9%) | 28 | (51.3%) |
| {±2 0 ∓2} | 338 | (18.2%) | 54 | (19.1%) | 25 | (17.5%) | 16 | (18.8%) | 12 | (20%) | 6 | (16.2%) |
| {±2 0 ∓2 0 ±2} | 133 | (7.1%) | 24 | (8.4%) | 10 | (7%) | 6 | (7%) | 4 | (6.6%) | 1 | (2.7%) |
| {±2 0 ∓2 0 ±2 0 ∓2} | 38 | (2.1%) | 7 | (2.4%) | 4 | (2.8%) | 2 | (2.4%) | 2 | (3.4%) | 1 | (2.7%) |
| {±2 0 ∓2 0 ±2 0 ∓2 0 ±2} | 16 | (1.1%) | 1 | (0.4%) | 1 | (0.7%) | 1 | (1.2%) | 1 | (1.7%) | 1 | (2.7%) |
| {±2 ∓2 ∓2} | 5 | (0.3%) | 1 | (0.4%) | 0 | (0.0%) | 0 | (0.0%) | 0 | (0.0%) | 0 | (0.0%) |
| TOTAL | 1853 | (100%) | 283 | (100%) | 142 | (100%) | 85 | (100%) | 60 | (100%) | 37 | (100%) |

TABLE II
Performance results with real LTO waveforms at P = 1,000

| Error Events in NRZ | NPMLD | | LNPMLD (2) | | LNPMLD (3) | | LNPMLD (5) | | LNPMLD (10) | | LNPMLD (50) | |
|---|---|---|---|---|---|---|---|---|---|---|---|---|
| {±2} | 1279 | (69.1%) | 278 | (61.2%) | 207 | (62.1%) | 181 | (63.5%) | 162 | (62.8%) | 158 | (63.7%) |
| {±2 0 ∓2} | 338 | (18.2%) | 98 | (21.6%) | 72 | (21.6%) | 62 | (21.7%) | 58 | (22.5%) | 54 | (21.7%) |
| {±2 0 ∓2 0 ±2} | 133 | (7.1%) | 43 | (9.5%) | 27 | (8.1%) | 24 | (8.4%) | 23 | (8.9%) | 20 | (8%) |
| {±2 0 ∓2 0 ±2 0 ∓2} | 38 | (2.1%) | 7 | (1.5%) | 4 | (1.2%) | 3 | (1%) | 3 | (1.1%) | 2 | (0.8%) |
| {±2 0 ∓2 0 ±2 0 ∓2 0 ±2} | 16 | (1.1%) | 3 | (1.1%) | 2 | (0.6%) | 2 | (0.7%) | 2 | (0.8%) | 2 | (0.8%) |
| {±2 ∓2 ∓2} | 5 | (0.3%) | 5 | (1.1%) | 5 | (1.5%) | 5 | (1.7%) | 5 | (1.9%) | 4 | (1.6%) |
| TOTAL | 1853 | (100%) | 454 | (100%) | 334 | (100%) | 285 | (100%) | 258 | (100%) | 248 | (100%) |

TABLE III
Performance results with real LTO waveforms at P = 2,000

| Error Events in NRZ | NPMLD | | LNPMLD (2) | | LNPMLD (3) | | LNPMLD (5) | | LNPMLD (10) | | LNPMLD (50) | |
|---|---|---|---|---|---|---|---|---|---|---|---|---|
| {±2} | 1279 | (69.1%) | 395 | (64.1%) | 334 | (65.7%) | 311 | (71%) | 296 | (67.6%) | 290 | (68.9%) |
| {±2 0 ∓2} | 338 | (18.2%) | 136 | (22%) | 107 | (21.1%) | 99 | (22.6%) | 95 | (21.7%) | 90 | (21.4%) |
| {±2 0 ∓2 0 ±2} | 133 | (7.1%) | 46 | (7.5%) | 35 | (6.9%) | 29 | (6.6%) | 28 | (6.4%) | 25 | (5.9%) |
| {±2 0 ∓2 0 ±2 0 ∓2} | 38 | (2.1%) | 8 | (1.3%) | 6 | (1.2%) | 5 | (1.1%) | 5 | (1.1%) | 4 | (0.9%) |
| {±2 0 ∓2 0 ±2 0 ∓2 0 ±2} | 16 | (1.1%) | 3 | (0.5%) | 2 | (0.4%) | 2 | (0.5%) | 2 | (0.5%) | 2 | (0.5%) |
| {±2 ∓2 ∓2} | 5 | (0.3%) | 5 | (0.8%) | 5 | (1%) | 5 | (1.1%) | 5 | (1.1%) | 4 | (0.9%) |
| TOTAL | 1853 | (100%) | 616 | (100%) | 508 | (100%) | 459 | (100%) | 438 | (100%) | 421 | (100%) |

Another observation that can be seen from these tables is that the distributions of these dominant error events (i.e. the percentages of the different types of error events) are roughly the same whether a List-NPMLD or a conventional NPMLD is used. This tends to suggest the idea that the proposed scheme may be effectively combined with some of the existing post processing methodologies. Such a combined design would be implemented in two steps: (Step 1) the List-NPMLD detection algorithm reduces the total number of error events without changing the distributions of error events, and (Step 2) an existing post processor focuses on the first one or two dominant error events and attempts to correct them. In this way, the combined post processor can improve performance even further.

As can, be seen, the proposed detection algorithm 12 and error correction system 10 achieve the reported performance gains by utilizing error detection codes 14 (illustrated in FIG. 1). In other words, the advantage of the List-NPMLD detection algorithm 12 is based on the extra redundancy allocated for error detection codes 14. However, this error detection capability can alternatively be provided by taking into account RLL and RS coding stages in a typical magnetic recording system, i.e., a joint design might be useful. For example, RLL decoding can be done during List-NPMLD detection and update steps. Once an illegal sequence (an invalid RLL codeword) is found, the associated path can be flagged 0 and should not be considered in further computations. Although the probability of causing illegal RLL sequences is low, they still can be used for error detection purposes in the proposed error correction system 10. On the other hand, one might use RS codes solely for error detection purposes. That is to say, during the List-NPMLD detection stage, after RLL decoding, RS decoding can take place to detect errors for each path. Although, this extra decoding stage adds an extra complexity into the system, error detection can be achieved and the overall system shall not need to use extra redundancy for error detection codes. It is again the complexity/redundancy trade-off that should be addressed based on the design specifications of the system in consideration.

As noted above, traditional post processors are suboptimum solutions and are usually not robust because they attempt to correct dominant error events at the expense of adding other unwanted errors (i.e. miss-correction). However, the proposed error correction system 10 has little chance of miss-correction because it always confirms the corrected sequence with EDC. Therefore, any potential miss-correction is inhibited as long as EDC functions properly.

The distributions of error events are functions of several parameters such as current recording density and the physical conditions of the read/write heads. As such parameters might change in time, the distributions of error events at the output of the NPMLDs may also change. Therefore, traditional approaches need to adaptively optimize the system parameters to obtain the reported performance gains. However, the proposed invention does not make any assumptions on the error event distribution and attempts to correct those error events without distinguishing one from the other. Therefore, the performance gain demonstrated herein can be effectively realized at any error event distributions.

While a number of exemplary aspects and embodiments of an error correction system 10 and a detection algorithm 12 (and related methods) have been discussed above, those of skill in the art will recognize certain modifications, permutations, additions and sub-combinations thereof. It is therefore intended that the following appended claims and claims hereafter introduced are interpreted to include all such modifications, permutations, additions and sub-combinations as are within their true spirit and scope.

What is claimed is:

1. A method for reducing the number of error events in a transmitted data stream, the method comprising the steps of:
generating at least a first most probable sequence and a second most probable sequence with a detection algorithm;
determining if a first correctable error occurred in the first most probable sequence with an EDC decoder; and
determining if a second correctable error occurred in the second most probable sequence with the EDC decoder.

2. The method of claim 1 wherein the steps of determining if a first correctable error occurred and determining if a second correctable error occurred are performed substantially simultaneously.

3. The method of claim 1 wherein the step of determining if a first correctable error occurred includes the EDC decoder having a first parity check code that is used to evaluate the first most probable sequence, and wherein the step of determining if a second correctable error occurred includes the EDC decoder having a second parity check code that is used to evaluate the second most probable sequence.

4. The method of claim 3 wherein the step of determining if a first correctable error occurred includes the first parity check code utilizing three parity bits that are added to a first portion of the transmitted data stream to evaluate the first most probable sequence, and wherein the step of determining if a second correctable error occurred includes the second parity check code utilizing three parity bits that are added to a second portion of the transmitted data stream to evaluate the second most probable sequence.

5. The method of claim 1 wherein the step of determining if a first correctable error occurred includes the EDC decoder having a first cyclic redundancy check code that is used to evaluate the first most probable sequence, and wherein the step of determining if a second correctable error occurred includes the EDC decoder having a second cyclic redundancy check code that is used to evaluate the second most probable sequence.

6. The method of claim 1 further comprising the step of separating the transmitted data stream into a plurality of data chunks, with each data chunk including a specified number of bits, and wherein the step of generating includes the detection algorithm generating at least a first most probable sequence and a second most probable sequence for each data chunk.

7. The method of claim 1 further comprising the steps of computing a plurality of path metrics for the transmitted data stream, and selecting a first q smallest path metrics out of the first most probable sequence and the second most probable sequence with a Q value selector.

8. The method of claim 7 wherein the step of determining if a first correctable error occurred includes evaluating the first q smallest path metrics with the EDC decoder to determine if a first correctable error occurred in the first most probable sequence, and wherein the step of determining if a second correctable error occurred includes evaluating the first q smallest path metrics with the EDC decoder to determine if a second correctable error occurred in the second most probable sequence.

9. The method of claim 8 further comprising the step of updating the plurality of path metrics based on the evaluation of the first q smallest path metrics by the EDC decoder.

10. A method for detecting bit errors in a transmitted data stream, the method comprising the steps of:
generating at least a first most probable sequence and a second most probable sequence with a detection algorithm;
computing a plurality of path metrics for the transmitted data stream; and
selecting a first q smallest path metrics out of the first most probable sequence and the second most probable sequence with a Q value selector.

11. The method of claim 10 further comprising the step of separating the transmitted data stream into a plurality of data chunks, with each data chunk including a specified number of bits, and wherein the step of generating includes the detection algorithm generating at least a first most probable sequence and a second most probable sequence for each data chunk.

12. The method of claim 10 further comprising the step of evaluating the first q smallest path metrics with an EDC decoder to determine if a first correctable error occurred in the first most probable sequence.

13. The method of claim 12 further comprising the step of evaluating the first q smallest path metrics with the EDC decoder to determine if a second correctable error occurred in the second most probable sequence.

14. The method of claim 12 further comprising the step of updating the plurality of path metrics based on the evaluation of the first q smallest path metrics by the EDC decoder.

15. An error correction system for reducing the number of error events in a transmitted data stream, the error correction system comprising a detection algorithm that detects bit errors in the transmitted data stream utilizing the method of claim 10; and an EDC decoder that determines (i) if a first correctable error occurred in the first most probable sequence, and (ii) if a second correctable error occurred in the second most probable sequence.

16. An error correction system for reducing the number of error events in a transmitted data stream, the error correction system comprising:
a detection algorithm that generates at least a first most probable sequence and a second most probable sequence; and
an EDC decoder that determines (i) if a first correctable error occurred in the first most probable sequence, and (ii) if a second correctable error occurred in the second most probable sequence.

17. The error correction system of claim 16 wherein the EDC decoder includes a first parity check code that is used to evaluate the first most probable sequence, and a second parity check code that is used to evaluate the second most probable sequence.

18. The error correction system of claim 16 wherein the EDC decoder includes a first cyclic redundancy check code that is used to evaluate the first most probable sequence, and a second cyclic redundancy check code that is used to evaluate the second most probable sequence.

19. The error correction system of claim 16 wherein the detection algorithm includes an update stage, wherein a plurality of path metrics are computed for the transmitted data stream, and wherein the update stage includes a Q value selector that selects the first q smallest path metrics out of the first most probable sequence and the second most probable sequence.

20. The error correction system of claim 19 wherein the EDC decoder evaluates the first q smallest path metrics to determine (i) if a first correctable error occurred in the first most probable sequence, and (ii) if a second correctable error occurred in the second most probable sequence.

21. The error correction system of claim 20 wherein the plurality of path metrics are updated based on the evaluation of the first q smallest path metrics by the EDC decoder.
